(19) United States
(12) Patent Application Publication
(10) Pub. No.: US 2007/0269975 A1
(43) Pub. Date: Nov. 22, 2007

(54) System and method for removal of photoresist and stop layer following contact dielectric etch

(76) Inventors: Stephen E. Savas, Fremont, CA (US); Li Hou, Cupertino, CA (US); Songlin Xu, Fremont, CA (US)

Correspondence Address: PRITZKAU PATENT GROUP, LLC, 993 GAPTER ROAD, BOULDER, CO, 80303, US

(21) Appl. No.: 11/436,950

(22) Filed: May 18, 2006

(51) Int. Cl. H01L 21/4763

(52) U.S. Cl. 438/637

(57) ABSTRACT

In device fabrication, a photoresist layer is formed on an insulation layer, above a stop layer that is supported directly on an active device structure. Holes are needed through the insulation layer to reach a contact arrangement, defined by the active device structure in which each contact is covered by the stop layer and some of the contacts include a silicide material. A plurality of contact openings are etched through the insulation layer to expose the stop layer above each contact, which may produce etch related residue. The photoresist and residues are then stripped using a first plasma that contains oxygen, without removing the stop layer such that the stop layer protects the silicide material from the oxygen. Thereafter, etching is performed to remove the stop layer from the contacts using a second plasma that is oxygen free and which contains hydrogen.

### BACKGROUND

A standard “contact” etching process opens holes through a silicon dioxide insulating layer which has been deposited upon a thin silicon nitride layer that covers and protects just-fabricated transistors as part of an active device structure. It is often currently performed in two consecutive, uninterrupted steps in one processing chamber, which is usually a reactive ion etching (RIE) reactor, typically employing parallel plate electrodes through which rf power is passed to create a capacitive discharge. The normal process sequence, for contact etching, involves first rapidly etching holes in a relatively thick silicon dioxide layer, followed by a reduced-power etch of the thin, typically silicon nitride, stop layer. The silicon dioxide dielectric, typically about 4000 Angstroms thick, covering the stop layer must be etched to completion, or very nearly so, though it has a different thickness above the gate region than above source and drain regions. This etching process is typically fast and aggressive to be cost-effective, so the process generally uses energetic ion bombardment provided by the RIE reactor to increase the etch rate and to obtain a desired vertical wall profile. The stop layer (typically about several to five hundred Angstroms thick) etching is usually performed immediately following the main silicon dioxide etching step and takes place while the photoresist still remains on the wafer. Because of the damage this ion bombardment would cause to sensitive junctions and because of the varying thickness of the silicon dioxide layer, the etching process for silicon dioxide is highly selective so that it does not penetrate the thin stop layer.

The stop layer is commonly formed of silicon nitride, but in future implementations, may be formed from other electrical insulator materials, and protects delicate silicide—which comprises the top layer of the junctions in the gate, source and drain regions of transistors—from a relatively aggressive silicon dioxide etching process. The stop layer is so named because the silicon dioxide etching process, which is highly polymerizing, slows down substantially and can be stopped soon after encountering this thin layer of material, so that the stop layer is not penetrated. The stop layer etching step, which generally continues immediately after the silicon dioxide etching step, employs a different gas mixture than the silicon dioxide etching step and typically uses a reduced amount of rf power, often provided to the wafer support pedestal, to reduce the energy of ions. Since the stop layer is typically very thin it can be rapidly and productively removed, even when the etching process has lower power and a much slower etching rate. Lower etching power is beneficial for the silicide since the silicide will be subjected to less energetic ion bombardment thereby causing less damage to the silicide, once the stop layer is penetrated.

Photoresist (PR) stripping is typically performed immediately following the two step etching process, detailed above, that is, following the stop layer etch. The currently used PR stripping (and in some cases residue conversion) process may be performed in one or two parts and is generally performed in a different chamber than the silicon dioxide etching process.

Turning to FIG. 1, a prior art photoresist stripping system is diagrammatically illustrated and generally indicated by the reference number 100. Photoresist stripping typically uses the system of FIG. 1 wherein a plasma source 102 is fed gas from a supply 104 through a set of tubes 106. Reactive species 110 from source 102 are distributed by a baffle system 112 to a processing chamber 114 within which stands a pedestal 116 which supports a wafer 120. When species 110 from source 102 react with photoresist 122 (shown on only a portion of the wafer surface) to produce volatile reaction products 124, the latter are pumped away, as indicated by arrows 126, via ducts 130.

Downstream stripping processes (such as seen in FIG. 1) with wafer temperatures usually above about 200 C, typically using oxygen as principal gas, have been prevalent for all major photoresist removal applications in transistor fabrication as part of IC manufacturing. Oxygen has been the gas of choice since the beginning of plasma based stripping, because atomic oxygen reacts more strongly with organic polymers and carbon than most other radicals. Higher reactivity of species makes stripping rates faster, and faster rates make stripping system productivity higher. Since there are typically twenty or more photoresist removal steps in the IC manufacturing process, high stripping rates, typically several microns per minute, have been valuable in stripping to keep IC costs low for mass-market products. As will be seen below, however, there are concerns at least relating to the use of oxygen with the ongoing advancement of silicon based IC technology.

A conventional stripping and residue removal process, performed following the contact and stop layer etching, generally uses mostly oxygen gas fed to a plasma source, and may use wet chemicals or have a small addition of forming gas or fluorinated gas added in a second step to remove residues. What must be removed is the patterned PR layer, still remaining above the insulator surface along with a substantial amount of polymer residue covering the sides of the hole in the principally silicon dioxide insulator layer as well as the sides of the photoresist mask, and covering the silicide at the bottom of the hole. This polymer residue contains mainly silicon, carbon and fluorine remaining from the silicon dioxide etching. In the commonly used current process, these residues as well as the photoresist need then to be removed while minimizing damage to the silicide. Generally, this process, as performed in reactors such as in FIG. 1, provides a copious amount of oxygen atoms to the wafer, at elevated wafer temperature (130 C to 250 C) and converts residues to a soft silicon dioxide layer, as well as stripping photoresist. Unfortunately, however, most silicide materials used for junctions, including cobalt silicide and nickel silicide, are sensitive to oxygen and degraded in performance by it. Further, the fluorine, that may be added in the residue removal step following the stripping, also attacks the silicide. Such reactive species as oxygen and fluorine radicals usually cause degradation of more than 10 Angstroms of the thickness of the silicide. In the past, including 130 nm IC technology, there has been sufficient thickness of silicide (or a protective sacrificial silicide used) that the material damaged by stripping and residue removal can afford to be lost without significantly increasing silicide resistance, thereby degrading circuit performance. It is recognized by Applicants, however, that, with very thin NiSi contact layers that are now going into production and will be used at the 65 nm silicon-based semiconductor technology node, the current processes for photoresist stripping and stop layer etching are detrimental to device performance and that there remains a need for improvement.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

A method is described as part of an overall technique for fabricating an integrated circuit on a wafer having an active device structure, during which fabrication, a patterned layer of photoresist is formed on an overall insulation layer this is itself supported directly on a stop layer that is, in turn, supported directly on the active device structure for using the patterned layer of photoresist in etching holes through the insulation layer to reach an electrical contact that is defined by the active device structure where each electrical contact of a plurality of the electrical contacts is covered by the stop layer and at least some of the electrical contacts include a silicide material and where a plurality of the holes are etched through the overall insulation layer such that one hole is associated with each electrical contact to at least partially expose the stop layer above each electrical contact and where etching of the holes, at least potentially, produces etch related residues.

In one feature, stripping the patterned layer of photoresist and the related residues is performed by etching using a first plasma that contains oxygen without substantially removing the stop layer such that the stop layer serves to protect the silicide material from the oxygen. After stripping with the first plasma, etching is performed to remove the stop layer from the contacts using a second plasma that is oxygen free, at least to an approximation, and which second plasma contains hydrogen gas.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be illustrative rather than limiting.

FIG. 1 is a diagrammatic view, in elevation, which illustrates a prior art system for stripping or ashing photoresist and related residues.

FIG. 2 is a diagrammatic view, in elevational cross-section, which illustrates an intermediate step in the processing of a workpiece in which a patterned photoresist layer is present on an insulator that may consist of one or more layers of dielectric materials.

FIG. 3 is a diagrammatic view, in elevational cross-section, which illustrates a contact hole etch including the formation of etch-related residues such that a contact hole is formed terminating within a stop layer.

FIG. 4 is a diagrammatic view, in elevational cross-section, which illustrates stripping of the patterned layer of photoresist and related residues from the contact hole.

FIG. 5 is a diagrammatic view, in elevational cross-section, which illustrates stop layer etching which follows the photoresist strip and residue removal.

FIG. 6 illustrates suitable process conditions for stripping photoresist and residue removal as performed in FIG. 4.

FIG. 7 illustrates suitable process conditions for stop layer etching as performed in FIG. 5.

FIG. 8 is a diagrammatic plan view of a system for use in performing the integrated sequence of processing described herein and in which double loadlocks are provided.

FIG. 9 is diagrammatic view, in perspective, of a plasma reactor that is suitable for performing stop layer etching in the system of FIG. 8.

### DETAILED DESCRIPTION

The following description is presented to enable one of ordinary skill in the art to make and use the invention and is provided in the context of a patent application and its requirements. Various modifications to the described embodiments will be readily apparent to those skilled in the art and the generic principles taught herein may be applied to other embodiments. Thus, the present invention is not intended to be limited to the embodiment shown but is to be accorded the widest scope consistent with the principles and features described herein including modifications and equivalents, as defined within the scope of the appended claims. It is noted that the drawings are not to scale and are diagrammatic in nature in a way that is thought to best illustrate features of interest. Descriptive terminology such as, for example, upper/lower and top/bottom has been adopted for purposes of enhancing the reader's understanding, with respect to the various views provided in the figures, and is in no way intended as being limiting.

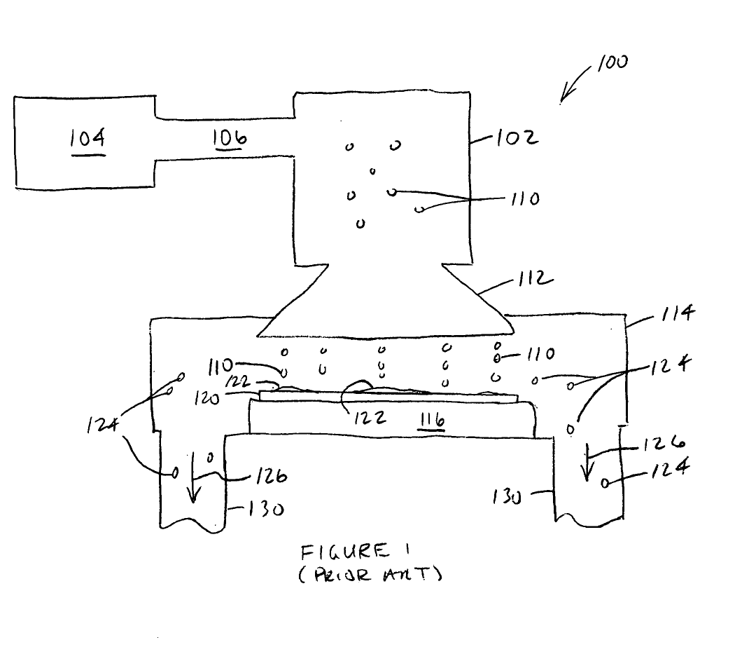

In the upcoming IC fabrication technology nodes, there will be some changes that will modify process requirements, for example, when using a downstream reactor, as shown in FIG. 1 and described above. For example, the thickness of photoresist layers is decreasing and will likely continue to decrease over the next several years. Deep Ultraviolet PR—currently the advanced resist for semiconductor fabrication at the 130 nanometer node—is normally coated in a thickness of about 600 nanometers or less. Older photoresist types such as g-line and I-line, still used for lower resolution patterning, are typically more than a micron thick. The leading edge photoresist for lithography (193 nanometer radiation) used in 90 nanometer semiconductor fabrication, started in many factories in 2004, will typically be about 400 nanometers thick or less. As critical dimensions shrink, in the next few technology generations, leading edge IC Fabs may use PR with thickness in the range from 200 nanometers to 300 nanometers. Finally, the Extreme Ultraviolet lithography systems, that will be needed in five to ten years from the date of this writing, will likely use resist with thicknesses of only 100 nanometers or a little more.

Due to the decreasing thickness of photoresist masks used for patterning contact holes, PR stripping processes in the future will not need to have such high rates of photoresist removal (about several microns per minute or more) to yield high productivity stripping systems. Since the photoresist layers for advanced lithography will be much thinner than currently used, it may be adequate for stripping processes to have rates on the order of several thousand Angstroms per minute to one micron per minute and still be economically competitive. At first blush, one might assume that reducing the strip rate, and thereby the penetrating nature of the reactive species in the aforedescribed conventional process, might serve to protect a silicide layer. Unfortunately, however, it should be remembered that relatively thinner silicide layers are that much more sensitive to the conventional strip process, as will be further discussed immediately hereinafter. Also, damage to silicide is self-limiting in depth and most occurs in the first 10 to 20 seconds of the process.

Other changes, beyond the subject of photoresist, are also likely to take place. For example, it is expected that the high conductivity material under the silicon nitride stop layer, but covering the junction—the electrical contact material—will be changing over the coming generations of semiconductor technology from cobalt silicide to nickel silicide for the 90 nm generation and possibly nickel-platinum silicide in the 65 nm or 45 nm generations of devices and getting much thinner. Whereas in the past and currently (130 nm to 90 nm IC technologies), for the source and drain regions of transistors, moderate loss, damage or oxidation of silicide has been acceptable, in future generations of semiconductor manufacturing technology, it is likely to be necessary to avoid too much loss of or damage to silicide at the exposed surfaces of the junction to maintain low contact resistance. Thicknesses of the silicide used in these areas, previously closer to 300 Angstroms or more, will soon be on the order of 200 Angstroms, and decreasing toward 100 Angstroms and, thus, loss of material or degradation of its electrical properties such as conductivity are less and less acceptable, particularly in view of the decreasing layer thickness.

Still considering the advanced use of silicide layers, it is further recognized that care should be taken to preserve the desired electrical properties of the silicide layer during a number of process steps. In this regard, future generations of integrated circuits, having a critical dimension of less than about 90 nanometers, will likely be increasingly dependent on protecting the silicide layers that serve as electrical connection points or junctions for the transistors being fabricated. As one example, the silicide should be protected during removal of a stop layer that directly overlies the silicide. As still another example, the silicide should be protected during photoresist stripping. It is submitted that conventional approaches for protecting the silicide layer impose limitations on the further advance of technology. Accordingly, improvements are needed, as will be further discussed below.

Applicants have found that, in conventional processing which removes the stop layer after the contact hole etch, but before photoresist removal, oxygen based stripping and cleaning causes significant damage to the NiSi, which is exposed at the bottom of the just-etched contact holes. In particular, Applicants recently completed experiments, with such exposed silicide, demonstrate that the sheet resistance of a 200 Angstrom thick NiSi layer is increased by about 10% to 15% by the action of a 30 second, conventional downstream stripping process using oxygen, even when that process is performed at the lower end of the range of temperatures (<200 degrees C.) normally used for photoresist stripping. This was also confirmed on a stripper using a different type of plasma source.

When Applicants exposed a silicide supporting wafer at 250 degrees Celsius to oxygen-based downstream stripping, the process was found to cause a 12% to 15% increase in the sheet resistance of the nickel silicide. Lowering the temperature to 200 degrees Celsius only slightly mitigated the damage, resulting in about a 10% increase in sheet resistance. While not intending to be bound by theory, the damage mechanism that increases sheet resistance of the NiSi probably involves the oxidation of the nickel silicide to silicon oxide and nickel. Such exposure decreases the electrical conductivity of the affected material and thereby reduces the speed of an IC sufficiently to lower the economic value of the IC. With this result in hand, it is submitted that new, even thinner junctions using Nickel Silicide will suffer substantially increased electrical resistance with even a modest amount of chemical damage such as oxidation of the silicide during such a photoresist strip, which follows a stop layer etching process. Therefore, Applicants recognize that there is an advantage in avoiding direct exposure of silicide to any oxygen-based dry stripping process.

Based on the foregoing, one way to avoid the damaging effects of oxygen-based stripping might be to use a gas feed to the plasma stripping source excluding oxygen. One alternative to oxygen-based feed gases for stripping is hydrogen. Applicants have found an increase in NiSi sheet resistance following direct exposure of the silicide to the hydrogen-based stripping process to be as low as 2% . This is much less than the roughly 10% minimal increase that was found when using oxygen-based gas mixtures. Unfortunately, however, Applicants have also discovered that residue removal with gas mixtures containing predominantly hydrogen, but effectively no oxygen, is limited as compared to what is achieved using mixtures based on oxygen. For example, purely downstream residue removal processes using hydrogen/nitrogen based process chemistries have been found recently by Applicants to need improvement with respect to removal of carbon polymer from the sides and bottom of just-etched contact holes. Such carbon polymer should be removed essentially completely for the electrical resistance of the connection to the transistor at the contact to be optimal. Thus, replacement of prior art oxygen-based process with a hydrogen-based process is not entirely adequate since there appear to be competing factors at least with respect to the removal of residue and protection of silicide properties when hydrogen-based and oxygen-based processes are compared.

In summary, while dry photoresist stripping processes using hydrogen gas rather than oxygen, following stop layer removal, produce substantially less damage to the nickel silicide than conventional oxygen-based stripping processes, in a downstream type of stripping reactor, such a hydrogen-based process is less than optimal as a mass production-worthy solution to the degradation of NiSi junctions by oxygen-based stripping in the conventional process sequence.

Applicants have found a new strip/stop layer etch integrated process that is less damaging to the silicide and more cost effective. This process is performed in a single system with photoresist strip and etching steps in a reverse order. That is, the photoresist stripping and residue removal is performed while the stop layer is intact, thereby protecting the silicide. Only after photoresist stripping is complete does the stop layer etching follow. Since the delicate silicide is protected by the stop layer, there is freedom to choose the stripping chemistry to be substantially oxygen or hydrogen-based and/or to include ion bombardment. Further, there is an option to add reasonable amounts of fluorine containing gas to either oxygen-based or hydrogen-based stripping gas mixture, in order to remove any silicon-based veils or structures that form from post-etch sidewall residues. Damage to the silicide is no longer a concern since the silicide is protected.

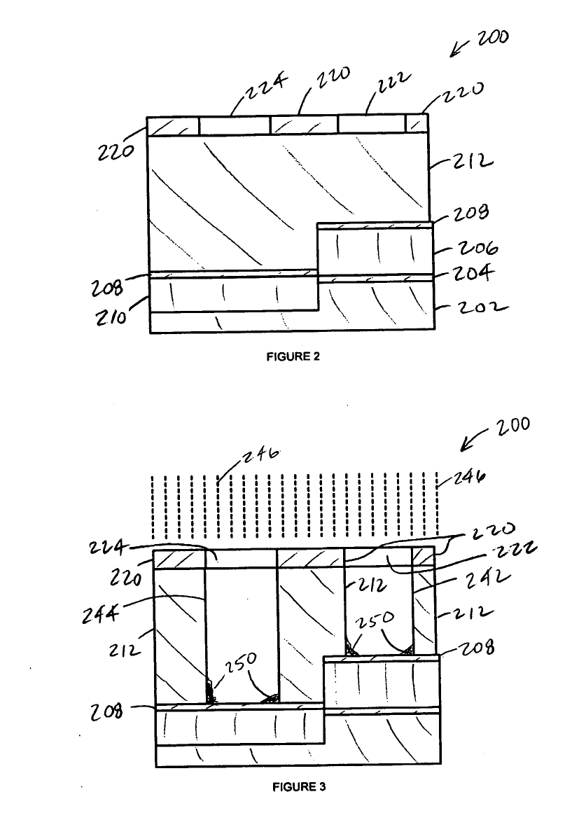

Referring to FIG. 2, a workpiece is diagrammatically illustrated in a partial, cross-sectional view and generally indicated by the reference number 200. A substrate 202 supports a gate dielectric 204 in a gate region. The substrate can comprise, for example, a wafer such as a silicon wafer. A gate electrode 206, that may be a metal or polysilicon or a silicide, is formed on gate dielectric 204. A stop layer 208 overlies gate electrode 206. Substrate 202 further includes a junction 210 formed therein. This junction, for example, can be a drain or source region of the device that is being produced. Junction 210, like gate electrode 206, is formed using a silicide material. Stop layer 208 also overlies junction 210. The foregoing structure, formed on substrate 202 supports a thick layer 212 of electrically insulative material which, in the present example, is silicon dioxide (SiO₂) and may be a compound layer, having an antireflective layer upon the SiO₂. Insulating layer 212 supports a patterned layer of photoresist 220 that is patterned to include a first aperture 222 that is generally aligned with gate electrode 206 and a second aperture 224 that is positioned above junction 210. The structure below and including gate electrode 206 and junction 210 may be referred to as an active device structure.

Attention is now directed to FIG. 3 which diagrammatically illustrates the appearance of workpiece 200 including etching contact openings or holes 242 and 244 through photoresist apertures 222 and 224 using a plasma 246. The contact holes are formed in insulating layer 212 such that stop layer 208 is exposed at the bottom of the contact holes. During the contact etch, polymer residues 250, which can contain carbon, can be formed in contact holes 242 and 244. These residues may extend across the bottom, vertically along the sidewalls of the contact holes, and on the inner surface of the photoresist. During conventional oxygen-based stripping this may form what is generally referred to as a veil.

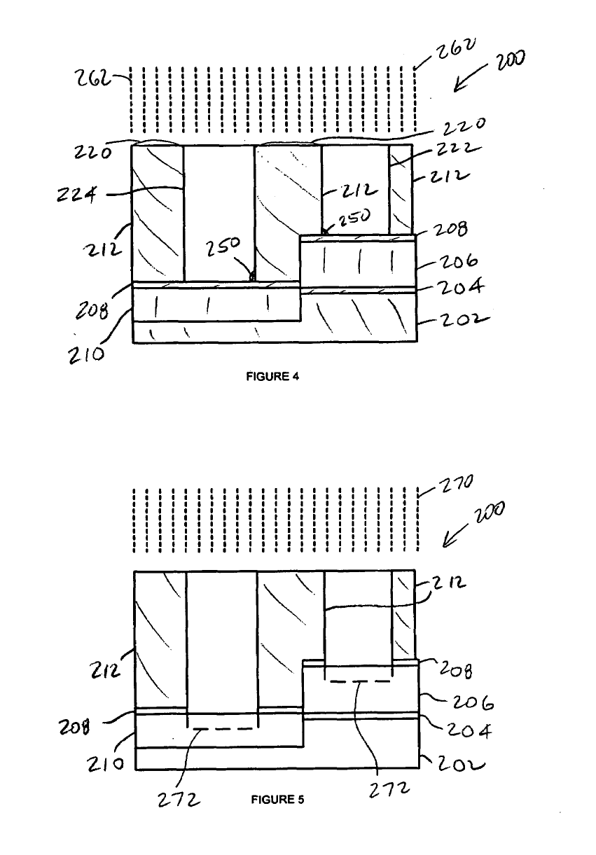

Referring to FIG. 4, removal of photoresist 220, from workpiece 200, is illustrated. With the silicide of contact 206 and junction 210 protected by stop layer 208, at least a portion of photoresist stripping, whether oxygen-based or otherwise, may be performed using an ion bombardment based process which exposes the structure to ions 262, for relatively quick removal of even tough carbon-based polymer residues 250 from the bottom of the contact hole. It is noted that such polymers are generally formed by the contact hole etch. This anisotropic stripping process may be performed at low wafer temperature, regardless of whether oxygen or hydrogen-based gases or mixtures are used. Acceptable productivity for future IC production at the 65 nm node and below is achieved at least for the reason that the photoresist will be much thinner than in previous IC technology generations. The ability of energetic and anisotropic ions to reach to the bottom of the just-etched contact holes assures that reactive species 262 can remove carbon from the polymer residues even near the bottom and at the edges proximate to the bottom of the contact hole. Once stripping and residue removal has been completed, upper surfaces of insulating layer 212 are exposed, along with stop layer 208.

Attention is now directed to FIG. 5, which illustrates a stop layer etch step that follows photoresist and residue removal, as described above. For purposes of performing the stop layer etch, a plasma 270 is used in one or more etching steps. In order to make the process sequence under discussion attractive in terms of process throughput and to achieve a high production yield, there are several aspects of the stop layer etching process that should be considered, which conventional processes and systems have not addressed. For example, with respect to this new sequence (where photoresist is removed prior to the stop layer), the photoresist mask no longer protects the upper layer of insulating, dielectric material 212. This insulating material may be silicon dioxide or any covering dielectric (typically, anti-reflective coating) layer. In this case, the edge of the contact hole in the dielectric, or any coating layer on top of the dielectric, is exposed to the same etching as the stop layer. This may cause a loss of material from the dielectric or covering layer and allows etching of exposed edges of dielectric materials that can produce faceting or rounding of that edge, thus increasing the effective diameter of the hole in the dielectric.

As will be seen, embodiments that are effective in removing the stop layer are characterized by a soft, but effective etching process so as to substantially limit damage to the delicate silicide in regions 272 (indicated using dashed lines in FIG. 5), as well as minimizing removal of, faceting or rounding of the edge of exposed dielectric 212. Such stop layer etching also permits the use of a relatively aggressive photoresist stripping and residue cleaning process, with the stop layer in place to protect the silicide. It has been found that this combined process allows an integrated circuit to exhibit reduced or low electrical contact resistance so as to improve transistor speeds for the upcoming 65 nm and 45 nm IC technology generations and beyond.

Etching processes activated by energetic ions, including oxygen or nitrogen, which sputter or damage material at the wafer surface, will increase contact sheet resistance due to loss of or damage to the silicide. Processes where there is ion bombardment, along with exposure to radicals of reactive species such as fluorine, will etch silicon and may also chemically damage the silicide to a depth that is a substantial fraction of the total thickness. Regardless of the mechanism, loss of even 10 Angstroms of such silicide results in the increase in sheet resistance for a 200 Angstrom thick silicide of about 5%, which can slow the transistor by about 5%. Applicants have found from measurements that the stop layer etching process disclosed herein is less damaging to the silicide, resulting in a smaller sheet resistance increase in NiSi than caused by conventional fluorocarbon-based stop layer etching processes which typically cause a greater than 10% increase in sheet resistance of the silicide. While not intending to be bound by theory, it is thought that the improvement in contact sheet resistance arises from reduced ion damage to the silicide. Further benefit is afforded by the presence of the stop layer during the photoresist strip.

The integration sequence (IS) of steps for the process that is the subject of the present disclosure generally is performed subsequent to the contact hole etch and includes (1) first stripping photoresist which may additionally remove some or all residues from the etching process, (2) removing remaining residues on the inside surface of the etched hole in both dielectric and PR followed by (3) etching through the stop layer which may include cleaning of the silicide surface. There may also be a separate fourth step, subsequent to the stop layer etch, in which the silicide surface exposed beneath the stop layer can be cleaned of remaining fluorine or carbon. This step may use pure hydrogen or hydrogen mixed with inert gas or gases. This IS, an alternative to the usual sequence, avoids damage to the silicide material of the junctions by removing photoresist and residues while the stop layer is still intact to protect the sensitive silicide at the junctions from chemical damage resulting from a stripping process. It is believed that this integration sequence has not been used heretofore for at least two principal reasons. First, since an adequately selective and gentle stop layer etching process was not known, it was believed that any stop layer etching process would consume too much of the exposed layers, and enlarge unacceptably the “contact” holes made in the contact hole etching step. Second, since the new IS would involve excessive chamber-to-chamber substrate transfers, system throughput would suffer, based on inefficient use of the etching chambers in an expensive etching system. That is, it would be necessary to process wafers in an etching chamber, then in a stripping chamber and finally again in the etching chamber. Although some etchers do have integrated stripping stations, even these systems are not able to efficiently process wafers in this new and advantageous sequence.

With respect to the stripping/residue removal procedure and stop layer etch procedure described herein, it should be appreciated that either procedure may be multi-step, and may have different gas compositions, gas pressures, wafer temperatures and plasma source configuration for each step. Different steps in the same procedure may be performed in different chambers. Some of the process steps may use hydrogen as exclusive or a main source of reactive gas. Through the use of these procedures damage to or loss of silicides such as, for example, Nickel Silicide or other exposed silicide, used to make contact to the source, drain and gate of each transistor, can be substantially reduced.

The handling and process control system used with the wafer processing chamber(s) can use separate load lock and wafer transfer chambers so as to greatly reduce the stirring up of very small particulates during the venting and pumping cycles needed to bring wafers into the evacuated process chamber. Such a two-stage handling system also reduces the risk of leakage of hydrogen into the atmosphere within the factory, reducing the risks of fire or explosion. The plasma reactor, that may be used for stripping and residue conversion as well as stop layer etching, may be an inductively coupled one having a grounded electrostatic shield between a plasma excitation coil and the reactor's dielectric vacuum wall. A parallel plate reactor can be used, having excitation power to one or both electrodes. Such a reactor may well control the ion energies in the stop layer etching process and thereby minimize rounding and widening of holes for electrical connections to the transistors, as it reduces damage to and etching of the delicate silicide.

### Stripping and Residue Removal/Conversion

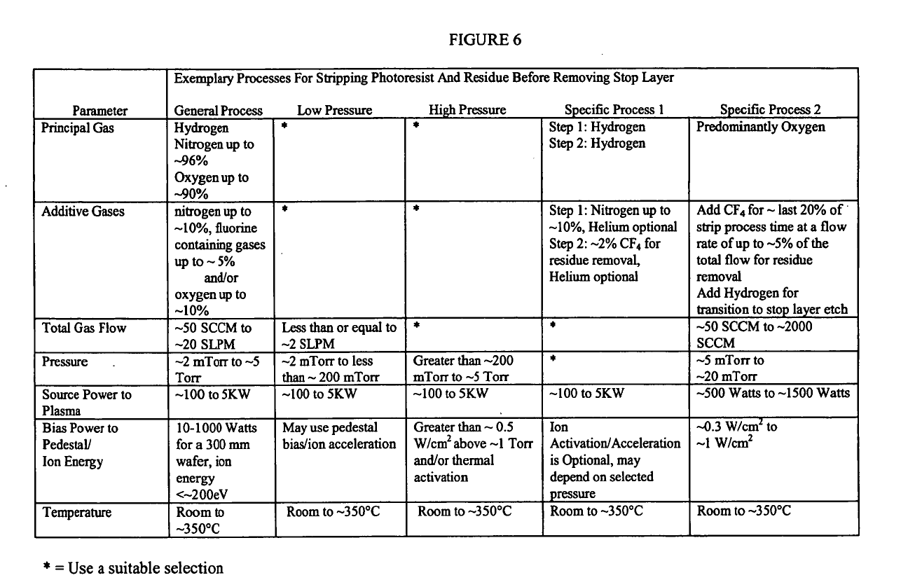

Turning now to FIG. 6, attention is now directed to a number of appropriate and exemplary embodiments of photoresist removal recipes that are set forth by this figure. Stripping with the described gas recipes may be accomplished in an automated PR stripping system that may use an rf discharge plasma as a source for generating reactive species from injected gas. The stripping and/or residue conversion step(s) may use ion bombardment or high wafer temperature to promote the stripping or removal reactions in any or all steps, although this is not required. The wafer or workpiece may be either remote from the plasma source for a stripping step or may be adjacent to the plasma source. Plasma generation may be accomplished using any of the well-known types of plasma sources such as, for example, microwave, inductively coupled or capacitively coupled sources. Particular care need not be taken in this step to control or limit the ion energy to very low values, although energies above a few hundred eV might produce faceting of the edge of the contact hole, previously made by the dielectric etching process. Generally, if the wafer is proximate to the plasma source, then either high or low temperature may be used, but if the wafer is remote from the plasma, the temperature generally may be above 100 degrees Celsius.

Still referring to FIG. 6, the disclosed stripping and residue removal/conversion process may be accomplished over a wide range of gas pressures, extending from about 2 mTorr to as much as about 5 Torr. Generally, the lower pressures between about 2 mTorr and a few hundred mTorr may be more appropriate for the ion-activated process whereas the higher pressures may be used for either ion or thermally activated processing. The power provided to the plasma reactor may generally vary between about 100 Watts to as much as about 5 kilowatts. Wafer temperature may be from room temperature up to about 350 degrees Celsius. The total flow of gas provided for the process may vary from about 50 standard cubic centimeters per minute to as much as about 20 thousand standard cubic centimeters per minute, i.e., 20 standard liters per minute (SLPM), the range depending on the pressure for the process step. Typically, processing at low pressures, generally less than about 200 mTorr can be performed with total process gas flow less than or about 2 standard liters per minute. Some step(s) in stripping resist or removing residues may also use ion bombardment of energetic ions to promote chemical reactions for stripping or residue conversion. Power provided to energize ions, in the event that ion bombardment is to be used, may vary between about 10 Watts to as much as about 1000 Watts for 300 mm size wafers, depending on the gas pressure and the amount of power used to generate the plasma. Higher bias power levels (above several hundred Watts for a 300 mm wafer) above about 0.5 Watts per Centimeter Squared of wafer area are generally more appropriate for higher gas pressures, typically above about 1 Torr.

### Gas Chemistry for Stripping and Residue Removal/Conversion

With continuing reference to FIG. 6, specific gas mixtures and process conditions for removing PR and converting or removing residues for each of these purposes are described. Stripping and residue removal steps in this process are not significantly damaging to the delicate silicide based on the new integration sequence in which PR and residues are removed prior to etching of the stop layer. While stripping and residue removal are accomplished first, with the stop layer intact, some embodiments may use hydrogen gas as the major reactive gas for both stripping and residue conversion or removal. Using little or no oxygen in stripping has the potential advantage of minimizing residual oxygen at the point when the stop layer etching exposes the silicide. Fluorine containing gases in modest amounts (up to about 5% fluorine) may be added to the hydrogen to accelerate the PR ashing and to aid in the removal/conversion of residues. Higher amounts will cause some degree of stop layer etching as the residue is being removed. In other embodiments, nitrogen or nitrogen containing gases may be added in at more than 50%, even contemplating the use of forming gas, such that nitrogen can be the principal gas. Other embodiments may use added oxygen to improve stripping rate in this IS and may use oxygen as the principal gas. Generally with regard to the gas chemistry during the stripping step, it should be appreciated that a considerable range of flexibility is provided as a result of the protection that is afforded by performing photoresist stripping with the stop layer in place. One two-step process embodiment, shown in FIG. 6, as Specific Process 1, uses hydrogen gas with about 10% nitrogen addition to strip resist, and hydrogen with about 2% fluorinated gas (CF₄ or other fluorocarbon) added after end point to hydrogen to remove residues. Helium may be added to the gas mixture if desired whether ion bombardment is used or not.

### A Particular Embodiment of Photoresist Removal and Residue Conversion

Still referring to FIG. 6, one embodiment of the disclosed process is designated as Specific Process 2, in which stripping and residue removal are performed using an electrostatically shielded inductive plasma reactor. The processing chamber includes an electrostatically shielded inductively coupled plasma source with a separately powered rf bias applied to the wafer holding pedestal. As one having ordinary skill in the art will appreciate, the pedestal temperature and the wafer temperature are generally independent of one another, while the use of an electrostatic chuck, for purposes of holding the wafer, causes the wafer temperature to at least generally track the pedestal temperature. The stripping and residue conversion step is performed first at a low pressure, between about 5 mTorr and 20 mTorr. Mainly oxygen is used for this step, where up to about 5 percent by flow rate of CF₄ may be added for the last 20% of the stripping process time to chemically break down silicon containing residues. Hydrogen may be added for purposes of residue removal, for example, serving to remove veils. A further purpose for presence of hydrogen resides in enabling a smooth transition to a stop layer etch in which oxygen is not used or is significantly reduced to the point of affecting maintaining the plasma. In this latter case, the hydrogen flow can be provided in order to avoid extinguishing the plasma as the oxygen flow is diminished and/or eliminated for purposes of the subsequent stop layer etch. It also allows hydrogen flow to be increased to levels needed for the following process step, the stop etch, without causing a burst of gas which could cause undesirable process effects or even plasma extinguishing. In making this transition, temperature compatibility between the photoresist stripping step and the stop layer etch step can also be considered. For example, if an at least relatively low temperature contact layer etch is to be performed, it may serve as an expedient, saving total process time, in the transition to use a relatively low temperature photoresist strip. The total gas flow may range from about 50 Sccm to as much as about 2000 Sccm. The power provided to the plasma source may be from about 200 Watts to about 2000 Watts with bias power from about 0.3 Watts per centimeter squared to about 1 Watt per centimeter squared. Typical processing is performed on either 200 mm or 300 mm diameter silicon wafers. The total time for this step depends on the photoresist thickness, but is typically about 30 seconds for photoresist of about 3000 Angstroms thickness, including time for over-etching, to ensure complete removal.

### Stop Layer Etching Step

In the context of the disclosed sequence with stop layer removal subsequent to photoresist stripping, a number of aspects for appropriate stop layer etching will now be described. First, to be successful, the stop layer etching process should avoid removing too much of the main silicon dioxide dielectric (item 212 in FIG. 5), or any dielectric (anti-reflective coating or otherwise) layer that covers the silicon dioxide that is left exposed after photoresist stripping. It should be appreciated that this differentiation is somewhat difficult, depending upon the materials. For example, such difficulty is encountered when the DARC layer (Dielectric Antireflective Coating) 212 is silicon oxynitride and stop layer 208 (FIG. 5) is silicon nitride. These are quite similar materials, which makes for a challenge in etching the silicon nitride at a much higher rate than the silicon oxynitride. Typical selectivities of conventional processes for silicon nitride etching, relative to silicon oxynitride, are very low—typically about 1.5 to 1.0. Such a poor selectivity would result in too much loss of silicon oxynitride, and thus is not considered by Applicants as acceptable for present purposes. Second, the stop layer etching process should avoid any substantial rounding or faceting of the edges of the contact hole, since this effectively increases the maximum diameter of the metal connection to the transistor and may cause shorting from one connection to an adjacent connection. Third, the stop layer etching process should not affect the diameter of the contact hole, below the surface or the sidewall angle of that hole. Fourth, the stop layer etching process should not cause undercutting of the silicon dioxide layer due to isotropic etching of the silicon nitride, especially following endpoint of this etching step, which would make it any wider at the base of the contact hole than above. Fifth, the stop layer etching process should cause little or no damage to the nickel silicide, once the stop layer has been penetrated in any location. Since the stop layer will inevitably be removed in some area(s) on the wafer before some other areas, it is desired that “over-etching” during what may be termed as an “over-etch period” does not excessively damage the delicate silicide in these areas, where early and complete removal of the stop layer is initially achieved. This process step has high selectivity of Si₃N₄ etching relative to NiSi or other silicides. In conjunction with this latter aspect, it is desired that the stop layer etching process be very uniform in its rate across the wafer. Further, for areas of initial removal of the stop layer, the etching process may use low or minimum ion energies to limit excessive ion penetration and damage of the silicide during the over-etch period.

### Gas Composition for Stop Layer Etch

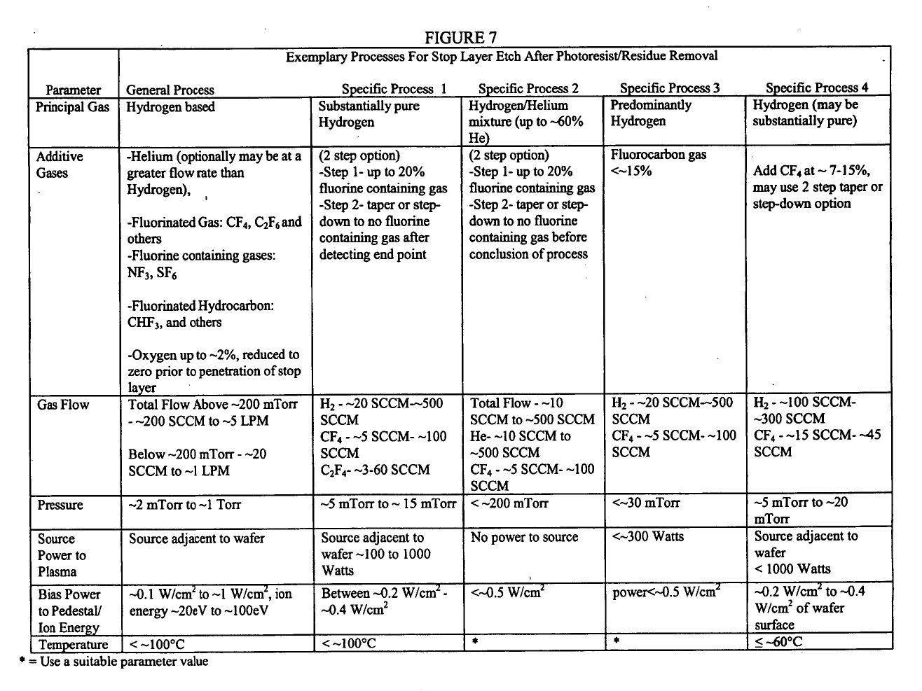

Referring to FIG. 7, in meeting the desired process aspects set forth immediately above, Applicants have discovered a number of embodiments wherein the etching of the stop layer is accomplished using a hydrogen-based gas mixture, including a fluorinated gas such as, for example, CF₄ or other fluorinated hydrocarbons, such as C₂F₆, CHF₃, and/or other fluorine containing gases such as NF₃ or SF₆, at least during an early part of the etching. Such process may use small amounts (up to approximately 10%) of oxygen in its early part, but should exclude oxygen in the later portion of stop layer etching—certainly prior to penetration of the stop layer in any location. Stop layer etching for this IS, in which photoresist stripping is performed prior to stop layer etching, may advantageously use ion bombardment to anisotropically remove the exposed stop layer. Lacking such ion activity, it is likely that for some stop layer etching processes there might be isotropic etching of the material at the sidewall of the contact hole that would cause the dimensions of the hole to increase and affect the device yield. It is extremely likely that such process would continue to etch the stop layer under the main dielectric, thus causing widening of the holes at the base and leaving voids after electrical connections are made to the junctions. In some embodiments, stop layer etching may be completed with substantially pure hydrogen or a mixture with helium to minimize sputtering of the silicide junction material as well as to scavenge fluorine from the bottom or sides of the hole. In most cases, it is acceptable to add some inert gases, especially helium, which in some cases, may be in even greater flow rates than the hydrogen. One may also add small amounts of nitrogen (up to about 10%) to the hydrogen to improve scavenging of the remaining carbon in the contact hole.

As illustrated by Specific Processes 1 and 2 in FIG. 7, during the early and main part of the stop layer etching process, up to about 20 percent or less of fluorine containing gas (as a percentage of the hydrogen flow) may be part of the gas mixture. In the later stages of stop layer removal, the fluorine may be stopped and the hydrogen gas (possibly diluted with helium or having a small amount of nitrogen) used proximate to completion of etching of the stop layer. This should minimize damage to the silicide, while removing fluorine and small amounts of carbon remaining from the etching process from the sidewalls and bottom of the contact hole. In particular, fluorine may be removed from the surface of the silicide which helps preserve its effective thickness and high electrical conductivity.

Referring to Specific Process 3, in FIG. 7, one embodiment of the stop layer etching process uses predominantly hydrogen gas, with a small flow of added fluorocarbon gas, fed to an inductively coupled plasma reactor with separate power supply for a plasma source and biasing of the pedestal. The gas pressure in the reactor is less than in the typical RIE reactor, under about 30 mTorr with injected gas being mainly hydrogen with less than about 15% added CF₄. Only modest rf power, less than or about 300 Watts is provided to the plasma source and in the range from approximately 0.1 W/cm² to approximately 0.4 W/cm² to the wafer holding pedestal. It should be appreciated that this stop layer etching follows what may have been a very aggressive ion-based photoresist stripping process, performed in an equivalent or in the same reactor, using substantially more rf power, both for the plasma source and for wafer bias, to rapidly and completely remove the photoresist and any carbon in the post-etch polymer.

### Other Characteristics of the Stop Layer Etching Step

Stop layer etching may be performed in the same chamber as the preceding photoresist stripping step, or in a different chamber. Embodiments using the new IS may be performed at elevated temperatures such as above 100 Celsius, but the etching of the stop layer can use ion bombardment to provide activation energy and can take place with wafer (or pedestal) temperature generally below or about 100 degrees Celsius. The process step for stop layer removal should be performed with the plasma of the source adjacent to the wafer. This plasma source may be inductively coupled and, in some embodiments, the source will have an electrostatic shield to prevent undesirable elevation of the plasma potential, due to capacitive coupling from induction coil to the plasma. The plasma source generally produces the needed ions as well as the neutral radicals to react with and volatize the Si from the SiN or other stop layer material, and to do so deep within the contact hole made in a previous step. To make the stop layer etching process anisotropic, it is usually necessary to have rf bias applied to the wafer holding pedestal. This bias power, when used in combination with an inductive plasma source, effectively adds energy that mainly provides added energy for ions that bombard the wafer. Bias power may be provided from the same source that generates the plasma and/or a separate source to increase energy of ions bombarding the wafer so that ion bombardment energies can be at or above about 20 eV and may in some embodiments be less than about 100 eV.

If there is no separately powered plasma source, inductive or microwave based or otherwise, and the etching is performed with a capacitive discharge then single or multiple sources of rf power may be used. In particular, in cases where electrodes have an inter-electrode gap that is small compared with the wafer radius it may be possible to apply different frequencies of rf power to both the pedestal and to the counter-electrode, which is normally a showerhead for gas introduction. In some embodiments, a higher frequency of rf power (>20 MHz) is applied to the showerhead to generate a plasma while one or more lower frequency sources of power are connected to the pedestal to provide energy to ions bombarding the wafer.

Whether applied as a separate bias power for an inductive plasma source, or for a capacitive discharge that is powered from the wafer-holding pedestal, typically, rf power in an amount between 0.1 Watts/centimeter squared and about 1 Watt/centimeter squared may be used. In the event that a narrow gap, capacitive rf discharge is used, where rf power is applied to the counter-electrode and not the wafer-holding pedestal, the amount of power to the counter electrode may generally be approximately equal to 0.1 to 1.0 Watts/cm². The power level to the pedestal, in any case, may be reduced by up to about 70% for the latter part of the stop-layer etching step to correspondingly reduce the energy of ions bombarding the silicide.

The gas pressure may be in the range from approximately 1 to 2 mTorr to as much as about 1 Torr. The total gas flow is, at least to a degree, usually dependent on the pressure of operation. Typically, pressures above approximately 300 mTorr may use total gas flow of between approximately 500 standard cubic centimeters per minute (Sccm) and about 5 standard liters per minute. Pressures below approximately 200 mTorr generally use less gas—typically a total gas flow from about 20 standard cubic centimeters per minute to about 2 standard liters per minute.

### A Particular Embodiment of the Stop Layer Etching Step

In one embodiment of the stop layer etching step, which is illustrated as Specific Process 4 in FIG. 7, mainly hydrogen is used as feed gas to which a Fluorine containing gas such as CF₄ (at about 7% to 15% of the total gas flow) is added. The gas pressure for the stop layer etching process can range from about 5 milliTorr to as much as about 20 milliTorr. There is rf power provided to the plasma source and a separate source of rf power to the pedestal supporting the wafer. The power supplied to the pedestal is modest, being between about 0.2 Watts per square centimeter of the wafer surface and about 0.4 Watts per square centimeter of wafer or pedestal surface that results in a low dc bias voltage. The time interval for etching depends on the thickness of the silicon nitride stop layer, but is typically between about 20 seconds and 45 seconds for a 400 Angstrom thick layer. It is of value in controlling the process that the potential of the plasma in the source be kept low so that the ion energies can be reduced to levels less than or about 50 eV such that damage to the silicide is minimal. This is accomplished, in one embodiment, by using an electrostatically shielded inductively coupled plasma source which is very efficient at producing ions and neutral radicals providing for a high etching rate with low ion energies. Excessive ion energies may cause unacceptable damage to the silicide layer, following penetration, and aggravate rounding of the edges of the contact hole, previously formed using a photoresist mask.

Applicants have found that the processing conditions immediately above result in an etching process with a surprisingly high “selectivity” ratio of etching rates of over 3 to 1 for silicon nitride relative to silicon oxynitride. The etching rate of the process for the silicon nitride ranges from about 900 Angstroms per minute to about 1200 Angstroms per minute, yet there is very little rounding or faceting (between about 60-120 Angstroms) of the corners of the contact hole. Further, the process completely cleared carbon residues in the contact hole, at least from a practical standpoint, and even with prolonged exposure did not excessively degrade the electrical conductivity of the NiSi layer.

### Wafer Handling and Plasma Reactor Apparatus For Integrated Strip/Residue Removal and Stop Etch Processes

In one embodiment of the stripping and etching system, a high-throughput type of handling and vacuum system is employed with stripping/etching chambers having an inductively coupled plasma source. Such a system can employ separate load lock and wafer handling chambers that can safely handle substantial flows of hydrogen gas, and permits low levels of particulate contamination, such that the process meets all requirements for mass production. Further, each process chamber may utilize inductively coupled plasma source(s) wherein an electrostatic shield assures that the plasma potential is well controlled.

In general, a plasma reactor chamber(s) consisting of plasma source plus wafer process station are part(s) of an automated PR stripping system including a robotic wafer handling system. In some cases, current wafer handling systems for stripping chambers may use a single stage vacuum load lock for wafers prior to inserting them into the vacuum chamber used for stripping. Non-loadlocked systems often release any remaining hydrogen gas in the process chamber into the environment and therefore they should not be used for stripping or etching processes employing large flows of hydrogen gas. Single load-lock systems make processing with substantial amounts of hydrogen gas somewhat safer, since they generally prevent hydrogen leakage to a degree that may lead to accumulation at atmospheric pressure that produces an explosion. However, even with these precautions, there can still be release of small amounts of hydrogen from such a system, because the loadlock alternately cycles to and from atmospheric pressure. Such hydrogen could possibly accumulate in any pockets in the ceiling of the factory with potentially dangerous consequences.

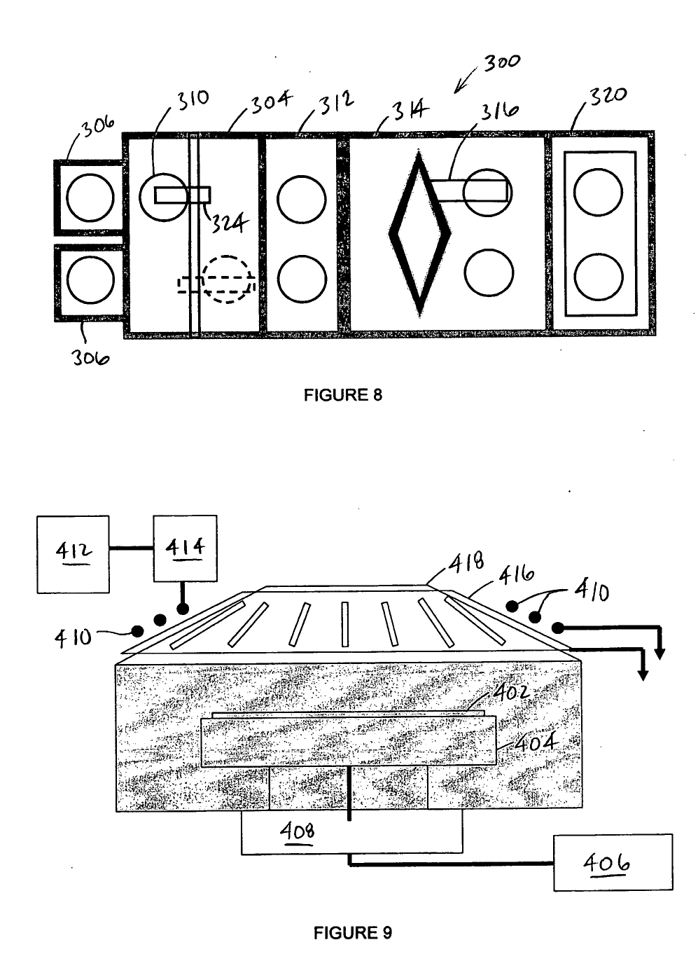

Turning to FIG. 8, one embodiment of a suitable wafer processing apparatus, for the IS addressed herein, is diagrammatically shown and is generally indicated by the reference number 300. System 300 may employ a wafer handling system with separate load-lock and wafer transfer chambers because it permits gas mixtures high in hydrogen gas to be reasonably safe. It further helps to reduce the stirring up of particulate that may be present in the wafer transfer chamber which often causes particulates to end up on the wafer. In such a stripping system, wafers are supplied for processing and returned from processing in cassettes or FOUPS 306 (the current term in IC manufacture for a closed pod that holds wafers) placed on load ports. The wafers from the cassettes/FOUPS are moved by an automated handling robot 310 into a first load lock 312 which can hold two wafers or more. The first load lock is evacuated and the door to a second load lock 314 is then opened. From first load lock 312, a wafer is brought into second load-locked chamber 314 by a vacuum robot 316. A door (not shown) to a processing chamber 320 is opened to remove a previously processed wafer and permit loading of a new wafer. The wafer to be processed is then moved into a processing chamber 320, after which the door is closed and the wafer is processed. The completed wafer is then removed from the processing chamber and returned to second load-lock 314 by vacuum robot 316 and placed into first load lock 312, under vacuum. First load lock 312 is then re-pressurized to atmospheric pressure and all wafers therein removed from the first load lock by an atmospheric robot 324. It is noted that this latter robot can moved wafers laterally, as shown in phantom. Processed wafers are then replaced into cassettes/FOUPS 306 from which they are ready to move to the next production step. It is noted that the wafer transfer chamber is always at vacuum. Furthermore, it may be operated so that it is open only to the process chamber when wafers are being loaded or unloaded into the process chamber.

In performing the stop layer etching process, it may be advantageous to do so with a plasma reactor that controls and minimizes the rf and/or dc potentials of the plasma in the reactor. This may benefit the process, since it results in lower and independently controllable energies for the ions bombarding the silicide when the etching process completes. Such lower energy ions may then do less damage to the silicide and may allow etching processes resulting in less increase in the sheet resistance of the silicide. Conventional parallel plate capacitive discharge-based etching reactors—in particular those with rf power frequencies of 13.56 MHz and below—may not have such low plasma potentials and truly independent control of the ion energy and ion density. Parallel plate capacitive discharge etching reactors with dual rf or uhf frequency power applied to the electrode(s), where one of the frequencies is at or above about 40 MHz while another is less than or equal to about 13.56 MHz, may satisfy the requirements for such control and minimization of ion energy. Inductively coupled plasma etching or stripping reactors with or without electrostatic shielding between excitation coil and dielectric window or plasma vessel may also be used in some embodiments of the disclosed system. Such a reactor can provide some degree of independent control of ion energy and density, and make possible low plasma potential and low ion energies.

With reference to FIG. 9, one suitable reactor for use in performing stop layer etching, as described above, is diagrammatically illustrated in a perspective view and generally indicated by the reference number 400. It is noted that two such configurations can be used in processing chamber 320 of FIG. 9, as indicated by the reference numbers 400a and 400b. A wafer 402 is supported on a pedestal 404 to which is connected an rf power supply 406 and in this case also a matching network 408 which may provide a variable and well controlled amount of rf power to the pedestal. A plasma 409 is generated in this embodiment of the plasma reactor by an induction coil 410 (diagrammatically indicated by a series of dots) to which a separate source of rf energy 412 is provided—in this case through a matching network 414. When power is provided to coil 410, the rf energy passes through an electrostatic shield 416 and through a window or dielectric vessel 418 into the plasma. The plasma thus generated is a source of ionized gas species and fragments of molecular feed-gas species, some of which are especially chemically reactive radicals.

Although each of the aforedescribed physical embodiments have been illustrated with various components having particular respective orientations, it should be understood that the present invention may take on a variety of specific configurations with the various components being located in a wide variety of positions and mutual orientations. Furthermore, the methods described herein may be modified in an unlimited number of ways, for example, by reordering, modifying and recombining the various steps. Accordingly, while a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

What is claimed is:

1. In an overall technique for fabricating an integrated circuit on a wafer having an active device structure, during which fabrication, a patterned layer of photoresist is formed on an overall insulation layer that is itself supported directly on a stop layer that is, in turn, supported directly on the active device structure for using the patterned layer of photoresist in etching holes through the insulation layer to reach an electrical contact that is defined by the active device structure where each electrical contact of a plurality of the electrical contacts is covered by said stop layer and at least some of said electrical contacts include a silicide material and where a plurality of said holes are etched through said overall insulation layer such that one hole is associated with each electrical contact to at least partially expose the stop layer above each electrical contact and where etching of said holes, at least potentially, produces etch related residues, a method comprising:
stripping said patterned layer of photoresist and said related residues by etching using a first plasma that contains oxygen without substantially removing said stop layer such that the stop layer serves to protect the silicide material from the oxygen; and
after said stripping, etching to remove said stop layer from said contacts using a second plasma that is oxygen free, at least to an approximation, and which second plasma contains hydrogen gas.

2. The method of claim 1 wherein said etching to remove the stop layer with said second plasma uses a fluorine containing gas that is added in an amount that is substantially less than said hydrogen gas.

3. The method of claim 2 wherein said etching using the second plasma, at least to an approximation, exposes said stop layer to radicals and ions formed from said hydrogen gas and said fluorine containing gas.

4. The method of claim 3 wherein said second plasma includes a fluorocarbon gas at less than approximately 15% of an amount of said hydrogen gas.

5. The method of claim 1 wherein etching to remove said stop layer includes at least initially exposing said stop layer to said second plasma generated using said hydrogen gas and a fluorine containing gas and, thereafter, at least concluding removal of said stop layer by generating said second plasma using a substantially pure hydrogen gas.

6. The method of claim 5 wherein said fluorine containing gas is a fluorocarbon gas in an amount that is less than approximately 15% of the hydrogen gas.

7. The method of claim 5 wherein said fluorine containing gas is CF₄ in a range of approximately 7%-14% of the hydrogen gas.

8. The method of claim 1 including performing said stripping at a temperature of no more than approximately 130 degrees C.

9. The method of claim 1 wherein said stripping forms said second plasma predominantly from oxygen gas.

10. The method of claim 9 including adding CF₄ to the first plasma prior to concluding said stripping for use in residue removal.

11. The method of claim 10 wherein said stripping is performed during a strip process time interval and said CF₄ is added for approximately 20% of a concluding portion of the strip process time interval.

12. The method of claim 11 wherein said CF₄ is added at a flow rate of no more than approximately 5% of a total gas flow.
